(19) United States
(12) Patent Application Publication
(10) Pub. No.: US 2023/0075665 A1
(43) Pub. Date: Mar. 9, 2023

(54) SEMICONDUCTOR PACKAGE AND METHOD OF MANUFACTURING THE SAME

(71) Applicant: Samsung Electronics Co., Ltd., Suwon-si (KR)

(72) Inventors: Wonkyun Kwon, Osan-si (KR); Jungseok Ahn, Seoul (KR); Kuyoung Kim, Seoul (KR)

(21) Appl. No.: 17/875,983

(22) Filed: Jul. 28, 2022

(30) Foreign Application Priority Data
Sep. 3, 2021 (KR) 10-2021-0117940

(51) Int. Cl. H01L 23/31; H01L 25/065; H01L 23/00; H01L 21/56

(52) U.S. Cl. CPC H01L 23/3135; H01L 25/0652; H01L 24/16; H01L 24/73; H01L 21/565; H01L 24/32; H01L 24/27; H01L 2924/1436; H01L 2924/1431; H01L 2924/10156; H01L 2924/10158; H01L 2224/2784; H01L 2924/1811; H01L 2924/1815; H01L 2924/182; H01L 2924/186; H01L 2224/16145; H01L 2224/16227; H01L 2224/16238; H01L 2224/32145; H01L 2224/32225; H01L 2224/3201; H01L 2224/32059; H01L 2224/32058; H01L 2224/73204; H01L 23/3675

(57) ABSTRACT

A semiconductor package includes a substrate, a plurality of semiconductor devices stacked on the substrate, an under-fill fillet on side surfaces of the plurality of semiconductor devices, and a molding resin surrounding the plurality of semiconductor devices. An uppermost end of the under-fill fillet includes a planar surface coplanar with an upper surface of a periphery of an uppermost semiconductor device among the plurality of semiconductor devices, and the molding resin completely covers the planar surface.

### CROSS-REFERENCE TO RELATED APPLICATION

This application is based on and claims priority under 35 U.S.C. § 119 to Korean Patent Application No. 10-2021-0117940, filed on Sep. 3, 2021, in the Korean Intellectual Property Office, the disclosure of which is incorporated by reference herein in its entirety.

### BACKGROUND

The inventive concept relates to a semiconductor package and a method of manufacturing the semiconductor package, and more particularly, to a semiconductor package capable of reducing an exterior defect of a product and increasing the product reliability, and a method of manufacturing the semiconductor package.

A non-conductive film (NCF) is frequently used as an under-fill used for packaging of a semiconductor device. However, as a size of the semiconductor device is reduced and a thickness thereof is reduced, various issues occur, and there is a need for improvement from an aspect of exterior inspection and product reliability.

### SUMMARY

The inventive concept provides a semiconductor package capable of reducing an exterior defect of a product and increasing product reliability.

The inventive concept also provides a method of manufacturing a semiconductor package capable of reducing an exterior defect of a product and increasing product reliability.

According to an embodiment of the inventive concept, a semiconductor package includes a substrate; a plurality of semiconductor devices stacked on the substrate; an under-fill fillet on side surfaces of the plurality of semiconductor devices; and a molding resin surrounding the plurality of semiconductor devices. An uppermost end of the under-fill fillet includes a planar surface coplanar with an upper surface of a periphery of an uppermost semiconductor device among the plurality of semiconductor devices. The molding resin completely covers the planar surface.

According to an embodiment of the inventive concept, a semiconductor package includes: a package substrate; an interposer substrate on the package substrate; a first semiconductor device and a second semiconductor device arranged side by side on the interposer substrate; and a molding resin surrounding side surfaces of each of the first semiconductor device and the second semiconductor device. The first semiconductor device includes: a buffer chip; a plurality of memory devices stacked on the buffer chip and connected with each other via through silicon vias (TSV); and an under-fill fillet on side surfaces of the plurality of memory devices. An uppermost end of the under-fill fillet includes a planar surface coplanar with an upper surface of a periphery of an uppermost memory device among the plurality of memory devices. The molding resin completely covers the planar surface.

According to an embodiment of the inventive concept, a semiconductor package includes: a substrate; a plurality of semiconductor devices stacked on the substrate; an under-fill fillet on side surfaces of the plurality of semiconductor devices; and a molding resin surrounding the plurality of semiconductor devices. A side surface of an uppermost semiconductor device among the plurality of semiconductor devices has an L-shaped recess. An uppermost end of the under-fill fillet is coplanar with a horizontal surface of the L-shaped recess.

According to an embodiment of the inventive concept, a method of manufacturing a semiconductor package includes: stacking a plurality of semiconductor devices on a substrate by using a non-conductive film (NCF); heating the NCF so that a portion of the NCF protrudes from side surfaces of the plurality of semiconductor devices and at least partially covers the side surfaces thereof to form a preliminary under-fill fillet; partially removing an upper end of the preliminary under-fill fillet arranged in a side direction of a top semiconductor device arranged at an uppermost portion of the plurality of semiconductor devices to form an under-fill fillet, an upper end of the under-fill fillet being coplanar with an upper surface of a periphery of the top semiconductor device; and forming a molding resin to surround a side surface of each of the plurality of semiconductor devices.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an embodiment;

FIG. 2 is a cross-sectional view of a first semiconductor device included in a semiconductor package, according to an embodiment;

FIG. 3 is an enlarged diagram of a region III in FIG. 2;

FIG. 4 is a partial enlarged diagram of a side portion of a top semiconductor chip, according to an embodiment;

FIG. 5 is a partial enlarged diagram of a side portion of a top semiconductor chip, according to an embodiment;

FIG. 6 is a cross-sectional view of a first semiconductor device included in a semiconductor package, according to an embodiment;

FIG. 7 is a partial enlarged diagram of a region VII in FIG. 6;

FIG. 8 is a flowchart of a method of manufacturing a semiconductor package, according to an example embodiment;

FIGS. 9A through 9G are side views illustrating a method of manufacturing a semiconductor package, according to embodiments;

FIGS. 10 and 11 are schematic diagrams illustrating a method of forming an L-shaped recess as illustrated in FIGS. 4 and 5, respectively; and

FIG. 12 is a schematic diagram illustrating a method of forming a third upper surface slanted at an angle with respect to a first upper surface in FIGS. 6 and 7.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted.

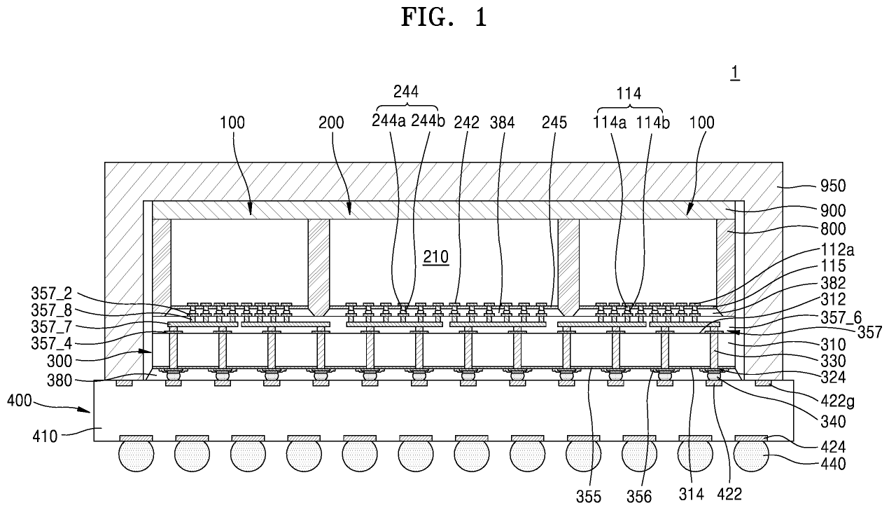

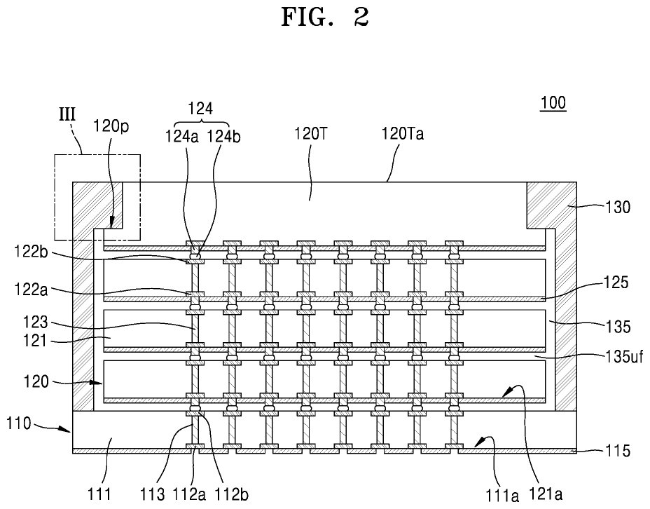

FIG. 1 is a cross-sectional view of a semiconductor package 1 according to an embodiment. FIG. 2 is a cross-sectional view of a first semiconductor device 100 included in the semiconductor package 1, according to an embodiment.

Referring to FIGS. 1 and 2, the semiconductor package 1 may include a second substrate 400, on which a first substrate 300 is mounted, and the first semiconductor device 100 and a second semiconductor device 200, which are mounted on the first substrate 300. The first semiconductor device 100 and the second semiconductor device 200 may be mounted adjacent to each other in a horizontal direction on a redistribution structure 357 of the first substrate 300. In this case, the first semiconductor device 100 and the second semiconductor device 200 may be spaced apart from each other in a lateral direction.

The first semiconductor device 100 and the second semiconductor device 200 may be electrically connected to the first substrate 300 via a plurality of first connection terminals 114 and a plurality of second connection terminals 244, respectively. The first semiconductor device 100 may include a plurality of first upper surface connection pads 112a, and the second semiconductor device 200 may include a plurality of second upper surface connection pads 242. The first substrate 300 may include a plurality of first redistribution pads 357_2. The plurality of first connection terminals 114 may be arranged between the plurality of first upper surface connection pads 112a and some of the plurality of first redistribution pads 357_2. The plurality of second connection terminals 244 may be arranged between the plurality of second upper surface connection pads 242 and the others of the plurality of first redistribution pads 357_2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

Each of the plurality of first connection terminals 114 may include a first conductive pillar 114a on the first upper surface connection pad 112a and a first conductive cap 114b on the first conductive pillar 114a. Each of the plurality of second connection terminals 244 may include a second conductive pillar 244a on the second upper surface connection pad 242 and a second conductive cap 244b on the second conductive pillar 244a.

The first semiconductor device 100 may include a first semiconductor chip 110 and a plurality of second semiconductor chips 120. In FIG. 2, the first semiconductor device 100 includes four second semiconductor chips 120, but is not limited thereto. For example, the first semiconductor device 100 may include two or more second semiconductor chips 120. In some embodiments, the first semiconductor device 100 may include a multiple of four second semiconductor chips 120. The plurality of second semiconductor chips 120 may be sequentially stacked on the first semiconductor chip 110 in a vertical direction. Each of the first semiconductor chip 110 and the plurality of second semiconductor chips 120 may be sequentially stacked so that an active surface thereof faces downward (that is, toward the first substrate 300).

The first semiconductor chip 110 may include a first semiconductor substrate 111 including a first semiconductor element 111a formed on the active surface thereof, the first upper surface connection pad 112a and a first lower surface connection pad 112b respectively arranged on the active surface and an inactive surface of the first semiconductor substrate 111, a first through electrode 113 penetrating at least a portion of the first semiconductor substrate 111 and electrically connecting the first upper surface connection pad 112a to the first lower surface connection pad 112b, and a first protective insulating layer 115 exposing at least a portion of the first upper surface connection pad 112a and covering the active surface of the first semiconductor substrate 111.

The first semiconductor substrate 111 may include or may be formed of, for example, a semiconductor material such as silicon (Si). In some embodiments, the first semiconductor substrate 111 may include or may be formed of a semiconductor element such as germanium (Ge), or a compound semiconductor such as silicon carbide (SiC), gallium arsenide (GaAs), indium arsenide (InAs), and indium phosphide (InP). The first semiconductor substrate 111 may include a conductive region, for example, a well doped with impurities. The first semiconductor substrate 111 may have various element isolation structures such as a shallow trench isolation (STI) structure.

In the inventive concept, an upper surface and a lower surface of a semiconductor substrate such as the first semiconductor substrate 111 may be referred to as an active surface and an inactive surface of the semiconductor substrate, respectively. For example, even when the active surface of the semiconductor substrate is below the inactive surface of a final product, the active surface of the semiconductor substrate may be referred to as the upper surface of the semiconductor substrate, and the inactive surface of the semiconductor substrate may be referred to as the lower surface of the semiconductor substrate. The terms ‘an upper surface’ and ‘a lower surface’ may be used for components arranged on the active surface and for components arranged on the inactive surface of the semiconductor substrate, respectively.

The first semiconductor element 111a may include various microelectronic elements, for example, a metal-oxide-semiconductor field effect transistor (MOSFET) such as a complementary metal-insulator-semiconductor (CMOS) transistor, an image sensor such as a system large scale integration (LSI) sensor, and a CMOS imaging sensor (CIS), a micro-electro-mechanical system (MEMS), an active element, and a passive element. The first semiconductor element 111a may be electrically connected to a conductive region of the first semiconductor substrate 111. The first semiconductor element 111a may be electrically separated from another first semiconductor element 111a adjacent thereto by an insulating layer.

In some embodiments, the first semiconductor chip 110 may include or may be, for example, a dynamic random-access memory (RAM) (DRAM) chip, a static RAM (SRAM) chip, a flash memory chip, an electrically erasable and programmable RAM (EEPROM) chip, a phase-change RAM (PRAM) chip, a magnetic RAM (MRAM) chip, or a resistive RAM (RRAM) chip. In some embodiments, the first semiconductor chip 110 may include or may be, for example, a central processing unit (CPU) chip, a graphics processing unit (GPU) chip, or an application processor (AP) chip.

In some embodiments, the first semiconductor chip 110 may include or may be a high bandwidth memory (HBM) DRAM semiconductor chip. In some embodiments, the first semiconductor chip 110 may include or may be a buffer chip including a serial-to-parallel conversion circuit. In some embodiments, the first semiconductor chip 110 may include or may be a buffer chip for controlling an HBM DRAM semiconductor chip. When the first semiconductor chip 110 includes or is a buffer chip for controlling the HBM DRAM semiconductor chip, the first semiconductor chip 110 may be referred to as a master chip, and the HBM DRAM semiconductor chip may be referred to as a slave chip.

In FIG. 2, the first upper surface connection pad 112a is illustrated as being within in the first semiconductor substrate 111, but is not limited thereto. In some embodiments, the first upper surface connection pad 112a may protrude from a surface of the first semiconductor substrate 111.

In some embodiments, the first semiconductor substrate 111 may include a base substrate including a semiconductor material, various conductive material layers formed on the base substrate and constituting the first semiconductor element 111a, an insulating material layer, a wiring pattern electrically connected to the first semiconductor element 111a, and a wiring via. In some embodiments, a semiconductor material may be a main material of the first semiconductor substrate 111. The present invention is not limited thereto. In some embodiment, a semiconductor material is not a main material of the first semiconductor substrate 111.

The second semiconductor chip 120 may include a second semiconductor substrate 121 including a second semiconductor element 121a formed on an active surface thereof, an inner upper surface connection pad 122a and an inner lower surface connection pad 122b respectively arranged on an active surface and an inactive surface of the second semiconductor substrate 121, a second through electrode 123 penetrating at least a portion of the second semiconductor substrate 121 and electrically connecting the inner upper surface connection pad 122a to the inner lower surface connection pad 122b, and a second protective insulating layer 125 exposing at least a portion of the inner upper surface connection pad 122a and covering the active surface of the second semiconductor substrate 121. The second protective insulating layer 125 may include or may be formed of an inorganic material such as oxide or nitride. For example, the second protective insulating layer 125 may include or may be formed of at least one of silicon oxide and silicon nitride. In some embodiments, the second protective insulating layer 125 may include or may be formed of silicon nitride.

The second semiconductor substrate 121, the inner upper surface connection pad 122a, the inner lower surface connection pad 122b, and the second through electrode 123 may be substantially the same as the first semiconductor substrate 111, the first upper surface connection pad 112a, the first lower surface connection pad 112b, and the first through electrode 113, respectively, and thus, detailed descriptions thereof are omitted.

The second semiconductor chip 120 may include or may be, for example, a DRAM chip, an SRAM chip, a flash memory chip, an EEPROM chip, a PRAM chip, an MRAM chip, or an RRAM chip. In some embodiment, the second semiconductor chip 120 may include or may be an HBM DRAM semiconductor chip. In some embodiments, the first semiconductor chip 110 may be referred to as a master chip, and the second semiconductor chip 120 may be referred to as a slave chip.

An inner connection terminal 124 may be attached to the inner upper surface connection pad 122a of each of the plurality of second semiconductor chips 120. The inner connection terminal 124 may electrically connect the first lower surface connection pad 112b of the first semiconductor chip 110 and the inner upper surface connection pad 122a of the second semiconductor chip 120 with each other, and may electrically connect the inner lower surface connection pad 122b and the inner upper surface connection pad 122a of the second semiconductor chip 120 with each other. The first lower surface connection pad 112b of the first semiconductor chip 110 and the inner upper surface connection pad 122a of the second semiconductor chip 120 may be vertically adjacent to each other. The inner lower surface connection pad 122b and the inner upper surface connection pad 122a of the second semiconductor chip 120 may be vertically adjacent to each other.

The inner connection terminal 124 may include an inner conductive pillar 124a on the inner upper surface connection pad 122a and an inner conductive cap 124b on the inner conductive pillar 124a.

A width and an area of the first semiconductor chip 110 may be greater than those of each of the plurality of second semiconductor chips 120. The first semiconductor device 100 may further include a molding resin 130 surrounding, on the first semiconductor chip 110, side surfaces of the plurality of second semiconductor chips 120, and a side surface and an upper surface of an under-fill fillet 135 to be described below. The molding resin 130 may include or may be formed of, for example, an epoxy mold compound (EMC).

An under-fill layer 135uf may be arranged between the first semiconductor chip 110 and the second semiconductor chip 120 at the lowermost end, and between the plurality of second semiconductor chips 120.

The under-fill layer 135uf between the first semiconductor chip 110 and the second semiconductor chip 120 at the lowermost end may surround the inner connection terminal 124, and may fill a space between the first semiconductor chip 110 and the second semiconductor chip 120 at the lowermost end. The under-fill layer 135uf may extend, in the horizontal direction, between the first semiconductor chip 110 and the second semiconductor chip 120 at the lowermost end, and may be connected to the under-fill fillet 135 on a side surface of the second semiconductor chips 120 at the lowermost end. The under-fill layer 135uf and the under-fill fillet 135 may form one body. For example, an under-fill may be referred to as the under-fill layer 135uf or as the under-fill fillet 135 depending on where the under-fill is formed.

The under-fill layer 135uf may be provided for improving adhesion strength of each component and/or preventing each component from physical strength deterioration due to deformation. In some embodiments, the under-fill layer 135uf may be provided for, for example, removing a space to which foreign materials or moisture infiltrates and preventing electrical migration.

In some embodiments, the under-fill layer 135uf may include a bisphenol-A (BPA) epoxy resin, a bisphenol-F (BPF) epoxy resin, an aliphatic epoxy resin, or a cycloaliphatic epoxy resin. In some embodiments, the under-fill layer 135uf may further include one or more types of inorganic particles selected from silica, alumina, zirconia, titania, ceria, magnesia, silicon carbide, and aluminum nitride.

The under-fill layer 135uf may be arranged between two second semiconductor chips 120. The under-fill layer 135uf between the two adjacent second semiconductor chips 120 may surround the inner connection terminal 124 and may fill a space between the two adjacent second semiconductor chips 120. The under-fill layer 135uf may extend between the plurality of second semiconductor chips 120 in the horizontal direction, and may be connected to the under-fill fillet 135 on the side surfaces of the plurality of second semiconductor chips 120.

The side surfaces of the under-fill fillet 135 may be completely covered by the molding resin 130. For example, the under-fill fillet 135 on the side surfaces of the molding resin 130 may not be exposed to the outside.

In some embodiments, a top semiconductor chip 120T that is uppermost of the plurality of second semiconductor chips 120 (i.e., an uppermost semiconductor chip 120T) may not include the inner lower surface connection pad 122b and the second through electrode 123. In some embodiments, a thickness of the top semiconductor chip 120T may be greater than a thickness of each of the second semiconductor chips 120.

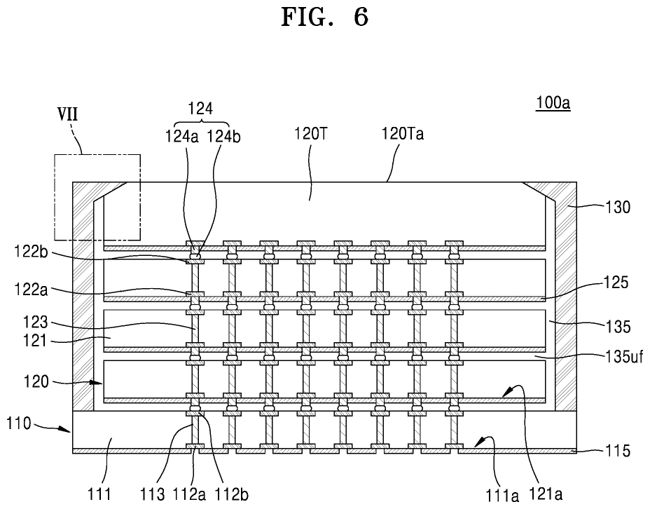

As illustrated in FIG. 2, the top semiconductor chip 120T may include a periphery 120p having a lower level than a first upper surface 120Ta, which is an uppermost surface of the top semiconductor chip 120T as illustrated in FIG. 2. In FIG. 2, the level of the periphery 120p is illustrated to be discontinuously lower than a level of the first upper surface 120Ta of the top semiconductor chip 120T. The present invention is not limited thereto. In some embodiments, the level of the periphery 120p may be continuously lowered from the level of the first upper surface 120Ta, as shown in FIG. 6, which will be described later.

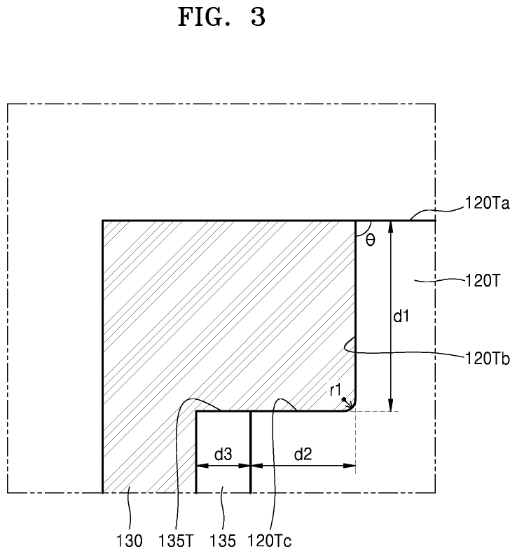

An upper surface of the under-fill fillet 135 may form one flat surface. In some embodiments, an uppermost end of the under-fill fillet 135 may have a planar surface. In some embodiments, the uppermost end of the under-fill fillet 135 may be coplanar with an upper surface of the periphery 120p of the top semiconductor chip 120T. FIG. 3 is an enlarged diagram of a region III in FIG. 2.

Referring to FIGS. 2 and 3, the top semiconductor chip 120T may include the first upper surface 120Ta, which is uppermost of the top semiconductor chip 120T, a side surface 120Tb continuously connected to the first upper surface 120Ta, and a second upper surface 120Tc connected to the side surface 120Tb and below the first upper surface 120Ta. In the embodiment, the second upper surface 120Tc in FIG. 3 may correspond to the periphery 120p of the top semiconductor chip 120T in FIG. 2.

In some embodiments, the first upper surface 120Ta and the side surface 120Tb may form an angle of about 90 degrees, and the first upper surface 120Ta and the second upper surface 120Tc may have an angle difference of less than about 10 degrees. For example, the first upper surface 120Ta and the second upper surface 120Tc may have an angle difference of equal to or less than about 10 degrees, equal to or less than about 9 degrees, equal to or less than about 8 degrees, equal to or less than about 7 degrees, equal to or less than about 6 degrees, equal to or less than about 5 degrees, equal to or less than about 4 degrees, or equal to or less than about 3 degrees. In some embodiments, the first upper surface 120Ta may be substantially parallel with the second upper surface 120Tc. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In some embodiments, an angle θ formed by the first upper surface 120Ta and the side surface 120Tb may be in a range of about 60 degrees (°) to about 150 degrees. In some embodiments, the first upper surface 120Ta and the side surface 120Tb may form an angle of about 60 degrees to about 150 degrees, about 70 degrees to about 130 degrees, about 80 degrees to about 110 degrees, about 85 degrees to about 100 degrees, or an arbitrary range between these numbers.

In some embodiments, a depth direction dimension d1 of the side surface 120Tb may be about 80 μm to about 200 μm. In some embodiments, the depth direction dimension d1 of the side surface 120Tb in the depth direction may be about 80 μm to about 200 μm, about 90 μm to about 190 μm, about 100 μm to about 180 μm, about 110 μm to about 170 μm, about 120 μm to about 160 μm, about 130 μm to about 150 μm, or in an arbitrary range between these numbers. When the first upper surface 120Ta is parallel with the second upper surface 120Tc, the depth direction dimension d1 may correspond to a level difference between the first upper surface 120Ta and the second upper surface 120Tc.

In some embodiments, the depth direction dimension d1 of the side surface 120Tb may be about 40% to about 80% of the total thickness of the top semiconductor chip 120T. In some embodiments, the depth direction dimension d1 of the side surface 120Tb may be about 40% to about 80%, about 45% to about 75%, about 50% to about 70%, about 55% to about 65%, or in an arbitrary range between these numbers of the total thickness of the top semiconductor chip 120T.

The second upper surface 120Tc and the side surface 120Tb may form an angle of about 90 degrees. In some embodiments, the second upper surface 120Tc and the side surface 120Tb may form an angle of about 80 degrees to about 100 degrees, about 82 degrees to about 98 degrees, about 84 degrees to about 96 degrees, about 85 degrees to about 95 degrees, about 86 degrees to about 94 degrees, about 87 degrees to about 93 degrees, about 88 degrees to about 92 degrees, about 89 degrees to about 91 degrees, or in an arbitrary range of these numbers.

In some embodiments, a width direction dimension d2 of the second upper surface 120Tc may be about 40 μm to about 100 μm. In some embodiments, the width direction dimension d2 of the second upper surface 120Tc may be about 40 μm to about 100 μm, about 45 μm to about 95 μm, about 50 μm to about 90 μm, about 55 μm to about 85 μm, about 60 μm to about 80 μm, or in an arbitrary range between these numbers.

A curved surface having a curvature radius r1 may be further between the second upper surface 120Tc and the side surface 120Tb. The curvature radius r1 may be, for example, about 1 μm to about 20 μm. In some embodiments, the curvature radius r1 may be about 1 μm to about 20 μm, about 2 μm to about 19 μm, about 3 μm to about 18 μm, about 5 μm to about 15 μm, about 7 μm to about 13 μm, about 8 μm to about 12 μm, or in an arbitrary range between these numbers.

The uppermost end of the under-fill fillet 135 may include a planar surface 135T, and the planar surface 135T may be substantially coplanar with the second upper surface 120Tc. A horizontal direction width d3 of the planar surface 135T may be about 20 μm to about 80 μm. In some embodiments, the horizontal direction width d3 of the planar surface 135T may be about 20 μm to about 80 μm, about 25 μm to about 75 μm, about 30 μm to about 70 μm, about 35 μm to about 65 μm, about 40 μm to about 60 μm, or in an arbitrary range between these numbers. Terms such as “same,” “equal,” “planar,” or “coplanar,” as used herein encompass near identically including variations that may occur, for example, due to manufacturing processes. The term “substantially” may be used herein to emphasize this meaning, unless the context or other statements indicate otherwise.

In some embodiments, when the side surface 120Tb forms an angle θ with respect to the first upper surface 120Ta, the planar surface 135T may form an angle of (180−θ) with respect to the side surface of the under-fill fillet 135. When the side surface 120Tb forms an angle of about 90 degrees with respect to the first upper surface 120Ta, the planar surface 135T may form an angle of 90 degrees with respect to the side surface of the under-fill fillet 135.

The planar surface 135T as well as the entire side surface of the under-fill fillet 135 may be covered by a molding resin 130. When a portion of the under-fill fillet 135 is exposed to the outside of the molding resin 130, the exposed portion thereof may cause an external defect of a product. There may be a possibility that moisture infiltrates through an interface between the under-fill fillet 135 and the molding resin 130, or between the under-fill fillet 135 and the top semiconductor chip 120T, and accordingly, the product reliability may be reduced.

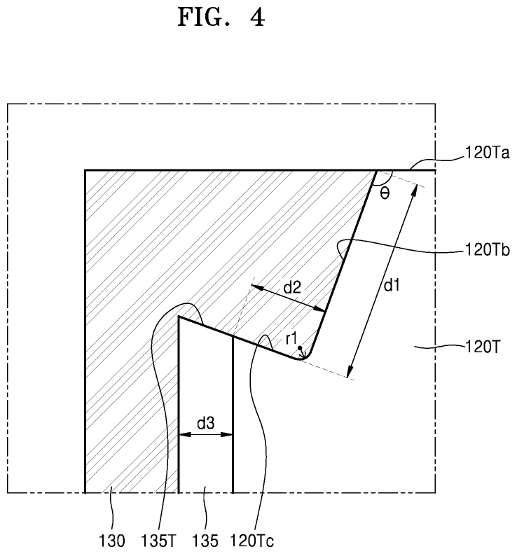

FIG. 4 is a partial enlarged diagram of a side portion of the top semiconductor chip 120T, according to an embodiment.

Referring to FIG. 4, the first upper surface 120Ta and the side surface 120Tb may form an obtuse angle with respect to each other. The angle θ formed by the first upper surface 120Ta and the side surface 120Tb may be greater than about 90 degrees (°) to equal to or less than about 150 degrees. In some embodiments, the first upper surface 120Ta and the side surface 120Tb may form an angle of about 95 degrees to about 150 degrees, about 100 degrees to about 145 degrees, about 105 degrees to about 140 degrees, about 110 degrees to about 135 degrees, about 115 degrees to about 130 degrees, about 120 degrees to about 125 degrees, or in an arbitrary range of these numbers.

Descriptions of the depth direction dimension d1 of the side surface 120Tb, the width direction dimension d2 of the second upper surface 120Tc, and the horizontal direction width d3 of the planar surface 135T may be the same as those given with reference to FIG. 3.

As described above, although the side surface 120Tb and the first upper surface 120Ta forms an obtuse angle, the side surface 120Tb and the second upper surface 120Tc may form an angle of about 90 degrees. In some embodiments, the second upper surface 120Tc and the side surface 120Tb may form an angle of about 80 degrees to about 100 degrees, about 82 degrees to about 98 degrees, about 84 degrees to about 96 degrees, about 85 degrees to about 95 degrees, about 86 degrees to about 94 degrees, about 87 degrees to about 93 degrees, about 88 degrees to about 92 degrees, about 89 degrees to about 91 degrees, or in an arbitrary range of these numbers.

A curved surface having the certain curvature radius r1 may be further between the second upper surface 120Tc and the side surface 120Tb, as described with reference to FIG. 3.

The uppermost end of the under-fill fillet 135 may include the planar surface 135T, and the planar surface 135T may be substantially on the same flat surface as the second upper surface 120Tc. The planar surface 135T and the side surface of the under-fill fillet 135 may form an acute angle. The acute angle may be a supplementary angle of the obtuse angle (that is, an angle formed by the first upper surface 120Ta and the side surface 120Tb).

As illustrated in FIG. 3, the planar surface 135T as well as the entire side surface of the under-fill fillet 135 may be covered by the molding resin 130. Accordingly, an exterior defect or reliability deterioration may be prevented.

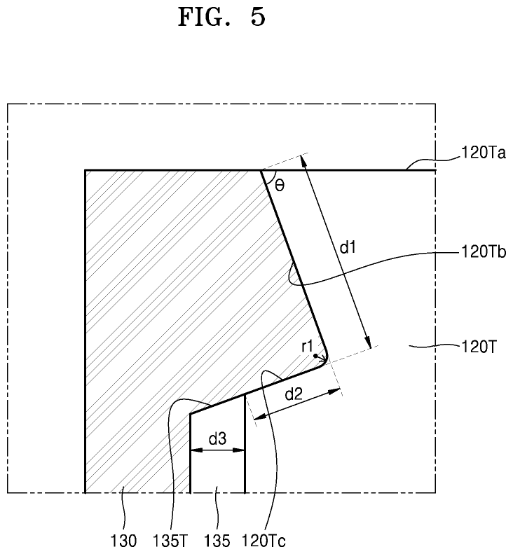

FIG. 5 is a partial enlarged diagram of a side portion of the top semiconductor chip 120T, according to an embodiment.

Referring to FIG. 5, the first upper surface 120Ta and the side surface 120Tb may form an acute angle with respect to each other. The angle 0 formed by the first upper surface 120Ta and the side surface 120Tb may be equal to or greater than about 60 degrees (°) to less than about 90 degrees. In some embodiments, the first upper surface 120Ta and the side surface 120Tb may form an angle of about 60 degrees to about 85 degrees, about 62 degrees to about 82 degrees, about 64 degrees to about 80 degrees, about 66 degrees to about 78 degrees, about 68 degrees to about 76 degrees, about 70 degrees to about 74 degrees, or in an arbitrary range of these numbers.

Descriptions of the depth direction dimension d1 of the side surface 120Tb, the width direction dimension d2 of the second upper surface 120Tc, and the horizontal direction width d3 of the planar surface 135T may be the same as those given with reference to FIG. 3.

As described above, although the side surface 120Tb forms an acute angle with respect to the first upper surface 120Ta, the side surface 120Tb may form an angle of about 90 degrees with respect to the second upper surface 120Tc. In some embodiments, the second upper surface 120Tc and the side surface 120Tb may form an angle of about 80 degrees to about 100 degrees, about 82 degrees to about 98 degrees, about 84 degrees to about 96 degrees, about 85 degrees to about 95 degrees, about 86 degrees to about 94 degrees, about 87 degrees to about 93 degrees, about 88 degrees to about 92 degrees, about 89 degrees to about 91 degrees, or in an arbitrary range of these numbers.

A curved surface having the curvature radius r1 may be further between the second upper surface 120Tc and the side surface 120Tb, as described with reference to FIG. 3.

The uppermost end of the under-fill fillet 135 may include the planar surface 135T, and the planar surface 135T may be substantially coplanar with the second upper surface 120Tc. The planar surface 135T may form an obtuse angle with respect to a side surface of the under-fill fillet 135. The obtuse angle may be a supplementary angle of the acute angle (that is, an angle formed by the first upper surface 120Ta and the side surface 120Tb).

As illustrated in FIG. 3, the planar surface 135T as well as the entire side surface of the under-fill fillet 135 may be covered by the molding resin 130. Accordingly, an exterior defect or reliability deterioration may be prevented.

Referring to FIG. 1, the second semiconductor device 200 may include a third semiconductor substrate 210, the second upper surface connection pad 242, a third protective insulating layer 245, and the second connection terminal 244. The second connection terminal 244 may include the second conductive pillar 244a on the second upper surface connection pad 242 and the second conductive cap 244b on the second conductive pillar 244a . The third semiconductor substrate 210, the second upper surface connection pad 242, the third protective insulating layer 245, and the second connection terminal 244 may include materials substantially similar to the first semiconductor substrate 111, the first upper surface connection pad 112a, the first protective insulating layer 115, and the first connection terminal 114, respectively, or may include materials substantially similar to the second semiconductor substrate 121, the inner upper surface connection pad 122a, the second protective insulating layer 125, and the inner connection terminal 124, respectively. The detailed descriptions thereof are omitted. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The second semiconductor device 200 may include or may be, for example, a CPU chip, a GPU chip, or an AP chip.

The first substrate 300 may include a base layer 310, a redistribution structure 357 arranged on a first surface 312 of the base layer 310, and a plurality of pad wiring layers 324 arranged on a second surface 314 of the base layer 310. The redistribution structure 357 may include a redistribution insulating layer 357_6. The redistribution structure 357 may further include a plurality of first redistribution pads 357_2 and a plurality of second redistribution pads 357_4 arranged on opposite surfaces of the redistribution insulating layer 357_ 6, respectively. For example, the plurality of first redistribution pads 357_ 2 may be arranged on an upper surface of the first substrate 300, and the plurality of pad wiring layers 324 may be arranged on a lower surface of the first substrate 300.

The base layer 310 may include or may be formed of a semiconductor material, glass, ceramic, or plastic. For example, the base layer 310 may include or may be formed of silicon. In some embodiments, the base layer 310 may be formed of a semiconductor substrate of silicon. A plurality of first substrate through electrodes 330 may penetrate the base layer 310. For example, the plurality of first substrate through electrodes 330 may extend from the first surface 312 of the base layer 310 to the second surface 314 of the base layer 310. The plurality of first substrate through electrodes 330 may be arranged inside the base layer 310. Each of the plurality of first substrate through electrodes 330 may include a conductive plug penetrating the base layer 310 and a conductive barrier layer surrounding the conductive plug. The conductive plug may have a circular shape, and the conductive barrier layer may have a cylindrical shape surrounding a side wall of the conductive plug. A plurality of via insulating layers may be arranged between the base layer 310 and the plurality of first substrate through electrodes 330, and may surround side walls of the plurality of first substrate through electrodes 330.

The redistribution structure 357 may include the redistribution insulating layer 357_6, and the plurality of first redistribution pads 357_2 and the plurality of second redistribution pads 357_4 arranged on opposite surfaces of the redistribution insulating layer 357_6. The plurality of second redistribution pads 357_4 may be arranged on the first surface 312 of the base layer 310, and may be electrically connected to the plurality of first substrate through electrodes 330. The plurality of first substrate through electrodes 330 may electrically connect the plurality of second redistribution pads 357_4 and the plurality of pad wiring layers 324 with each other.

The redistribution structure 357 may further include a plurality of redistribution lines 357_7 electrically connecting the plurality of first redistribution pads 357_2 to the plurality of second redistribution pads 357_4, and a plurality of redistribution vias 357_8. In FIG. 1, the plurality of redistribution lines 357_7 are illustrated as being inside the redistribution insulating layer 357_6, but are not limited thereto.

In some embodiments, each of the plurality of first redistribution pads 357_2, the plurality of second redistribution pads 357_4, the plurality of redistribution lines 357_7, and the plurality of redistribution vias 357_8 may include or may be formed of copper, nickel, stainless steel, or a copper alloy such as beryllium copper. For example, the redistribution insulating layer 357_6 may include or may be formed of at least one of oxide, nitride, and photo imageable dielectric (PID). In some embodiments, the redistribution insulating layer 357_6 may include or may be formed of silicon oxide, silicon nitride, epoxy, or polyimide.

On the second surface 314 of the base layer 310, a first substrate protective layer 355, the plurality of pad wiring layers 324 arranged on the first substrate protective layer 355 and connected to the plurality of first substrate through electrodes 330 penetrating the first substrate protective layer 355, a plurality of first substrate connection terminals 340 arranged on the plurality of pad wiring layers 324, and a plurality of wiring protection layers 356 surrounding the plurality of first substrate connection terminals 340 and covering the plurality of pad wiring layers 324 may be disposed.

The first substrate 300 may include an interposer.

A first adhesive film layer 382 may be arranged between the first semiconductor device 100 and the first substrate 300, and a second adhesive film layer 384 may be arranged between the second semiconductor device 200 and the first substrate 300. The first adhesive film layer 382 and the second adhesive film layer 384 may surround the first connection terminal 114 and the second connection terminal 244, respectively. In some embodiments, the first adhesive film layer 382 may protrude from the side surface of the first semiconductor device 100 in the lateral direction. In some embodiments, the second adhesive film layer 384 may protrude from the side surface of the second semiconductor device 200 in the lateral direction.

The second substrate 400 may include a base board layer 410. The second substrate 400 may further include a board upper surface pad 422 and a board lower surface pad 424 respectively arranged on an upper surface and a lower surface of the base board layer 410. In some embodiments, the second substrate 400 may include a printed circuit board. For example, the second substrate 400 may include a multi-layer printed circuit board. The base board layer 410 may include or may be formed of at least one material of phenol resin, epoxy resin, and polyimide.

A solder resist layer (not illustrated) exposing the board upper surface pad 422 and the board lower surface pad 424 may be formed on the upper surface and the lower surface of the base board layer 410, respectively. The first substrate connection terminal 340 may be connected to the board upper surface pad 422, and a package connection terminal 440 may be connected to the board lower surface pad 424. The first substrate connection terminal 340 may electrically connect the plurality of pad wiring layers 324 and the board upper surface pad 422 with each other. The package connection terminal 440 connected to the board lower surface pad 424 may connect the semiconductor package 1 to an external device.

The package connection terminal 440 may have greater dimensions (for example, a diameter) than the plurality of first connection terminals 114, the plurality of second connection terminals 244, and the first substrate connection terminal 340. The first substrate connection terminal 340 may have greater dimensions (for example, a diameter) than the plurality of first connection terminals 114 and the plurality of second connection terminals 244.

A board adhesive film layer 380 may be arranged between the first substrate 300 and the second substrate 400. The board adhesive film layer 380 may surround the plurality of first substrate connection terminals 340.

The semiconductor package 1 may, on the first substrate 300, further include a package molding layer 800 surrounding side surfaces of the first semiconductor device 100 and the second semiconductor device 200. The package molding layer 800 may include or may be formed of, for example, EMC.

In some embodiments, the package molding layer 800 may cover an upper surface of the first substrate 300 and the side surface of each of the first semiconductor device 100 and the second semiconductor device 200, but may not cover the upper surfaces of the first semiconductor device 100 and the second semiconductor device 200. The semiconductor package 1 may further include a heat dissipating member 950 covering the upper surfaces of the first semiconductor device 100 and the second semiconductor device 200. The heat dissipating member 950 may include a heat dissipating plate such as a heat slug or a heat sink. In some embodiments, the heat dissipating member 950 may, on the upper surface of the second substrate 400, surround the upper surfaces and side surfaces of the first semiconductor device 100, the second semiconductor device 200, and the first substrate 300. In some embodiments, the heat dissipating member 950 may include a flat plate or a solid of a metal material.

In some embodiments, the heat dissipating member 950 may block an electronic wave and dissipate heat, and may be connected to a board upper surface ground pad 422g including a ground of the plurality of board upper surface pads 422 of the second substrate 400.

The semiconductor package 1 may include a thermal interface material (TIM) 900 arranged between the heat dissipating member 950, and each of the first semiconductor device 100 and the second semiconductor device 200. The TIM 900 may include or may be formed of paste, or a film.

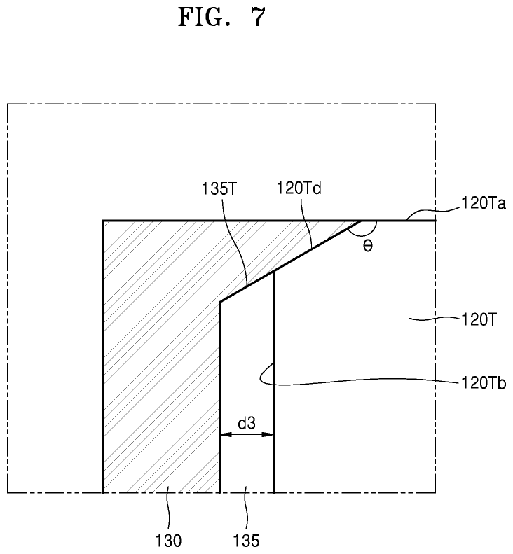

FIG. 6 is a cross-sectional view of a first semiconductor device 100a included in the semiconductor package 1, according to an embodiment. FIG. 7 is an enlarged diagram of a region VII in FIG. 6. The first semiconductor device 100a of the embodiment has a difference from the first semiconductor device 100 described with reference to FIG. 2 in a structure of a side surface portion of the top semiconductor chip 120T, and thus, such difference is mainly described below.

Referring to FIGS. 6 and 7, the top semiconductor chip 120T may include the first upper surface 120Ta that is uppermost and a third upper surface 120Td connected to the first upper surface 120Ta and slanted at an angle with respect to the first upper surface 120Ta.

The third upper surface 120Td may form an angle of about 5 degrees to about 80 degrees with respect to the first upper surface 120Ta. In some embodiments, an angle formed by the third upper surface 120Td and the first upper surface 120Ta may be about 5 degrees to about 80 degrees, about 10 degrees to about 75 degrees, about 15 degrees to about 70 degrees, about 20 degrees to about 65 degrees, about 25 degrees to about 60 degrees, about 30 degrees to about 55 degrees, about 35 degrees to about 50 degrees, about 40 degrees to about 45 degrees, or an arbitrary range of these numbers.

As described with reference to FIG. 2, the top semiconductor chip 120T may include a periphery having a lower level than the first upper surface 120Ta, and in the embodiments of FIGS. 6 and 7, the third upper surface 120Td may correspond to an upper surface of the periphery 120p.

The top semiconductor chip 120T may further include a side surface 120Tb connected to the third upper surface 120Td. In some embodiments, the side surface 120Tb may form an angle of about 90 degrees with respect to the first upper surface 120Ta.

The uppermost end of the under-fill fillet 135 may include the planar surface 135T, and the planar surface 135T may be substantially coplanar with the third upper surface 120Td. The horizontal direction width d3 of the planar surface 135T may be about 20 μm to about 80 μm. In some embodiments, the horizontal direction width d3 of the planar surface 135T may be about 20 μm to about 80 μm, about 25 μm to about 75 μm, about 30 μm to about 70 μm, about 35 μm to about 65 μm, about 40 μm to about 60 μm, or in an arbitrary range between these numbers.

In some embodiments, when the third upper surface 120Td forms the angle θ with respect to the first upper surface 120Ta, the planar surface 135T may form an angle of (270−θ) with respect to the side surface of the under-fill fillet 135. For example, when the third upper surface 120Td forms an angle of about 120 degrees with respect to the first upper surface 120Ta, the planar surface 135T may form an angle of 150 degrees with respect to the side surface of the under-fill fillet 135.

The planar surface 135T may contact the molding resin 130. In some embodiments, the entire supper portion of the planar surface 135T may contact the molding resin 130, and may be covered by the molding resin 130. The entire side surface of the under-fill fillet 135 may be covered by the molding resin 130.

As described with reference to FIGS. 2 and 3, when a portion of the under-fill fillet 135 is exposed to the outside of the molding resin 130, the exposed portion thereof may cause an exterior defect of a product. Moisture may infiltrate through an interface between the under-fill fillet 135 and the molding resin 130, or an interface between the under-fill fillet 135 and the top semiconductor chip 120T. The infiltrated moisture may generate an exterior defect, and accordingly, the product reliability of a package may be reduced. In some embodiments, the periphery 120p of the top semiconductor chip 120T may be partially removed such that an interface between the under-fill fillet 135 and the top semiconductor chip 120T is partially recessed below the first upper surface 120Ta thereof, thereby providing a space for accommodating a portion of the molding resin 130. The portion of the molding resin 130 may block the interface between the under-fill fillet 135 and the top semiconductor chip 120T from moisture, without increasing the height of the first semiconductor device 100.

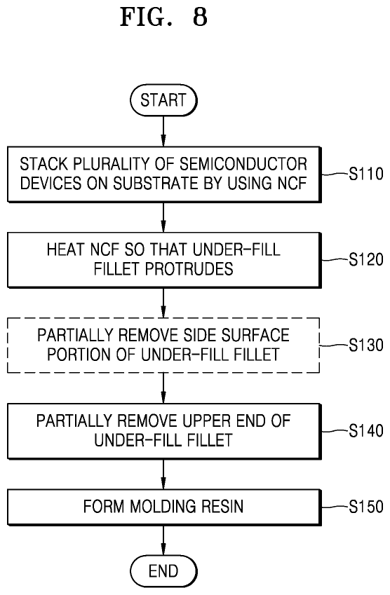

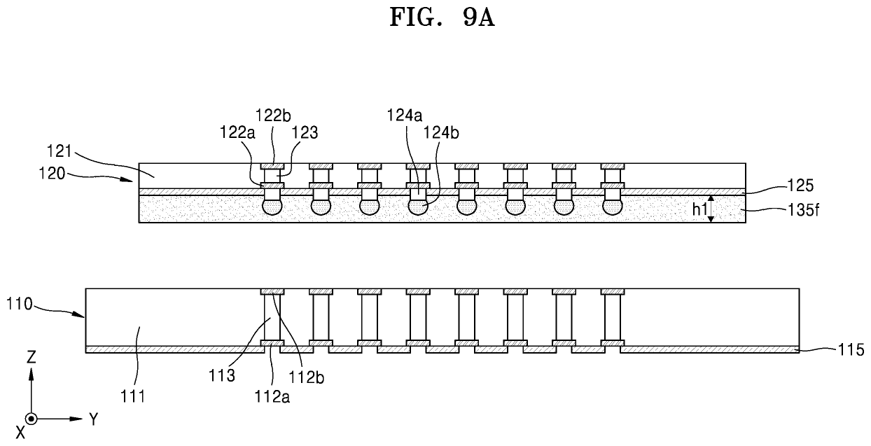

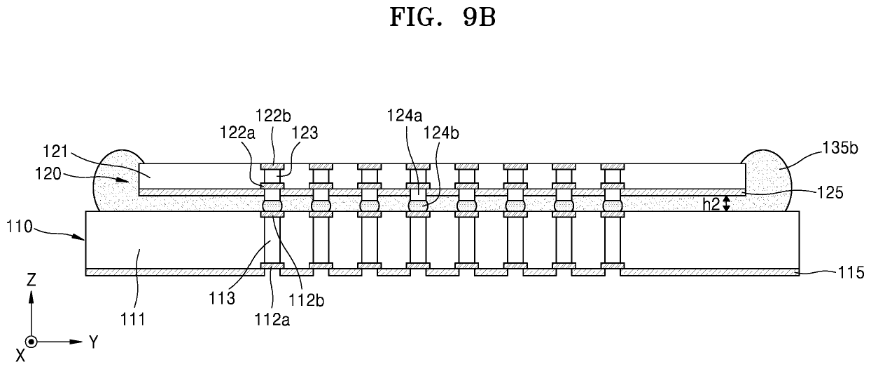

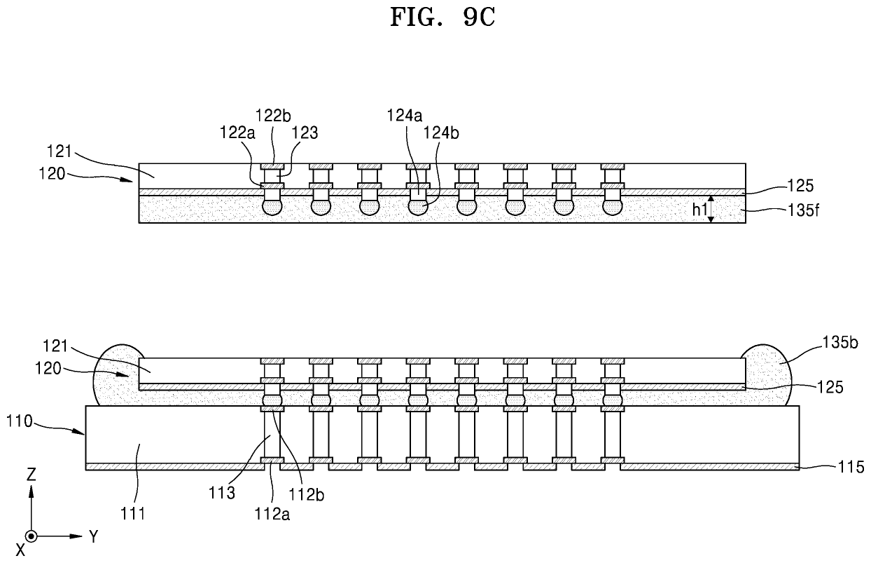

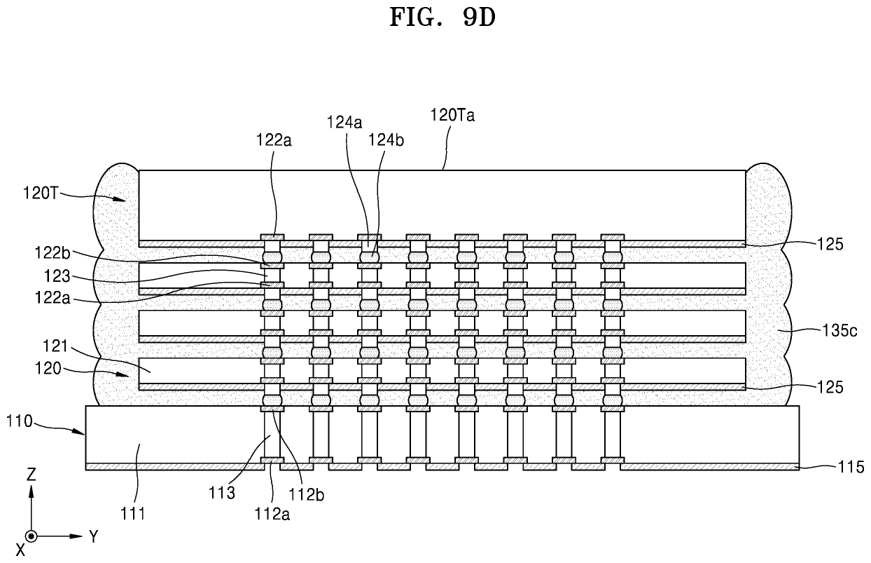

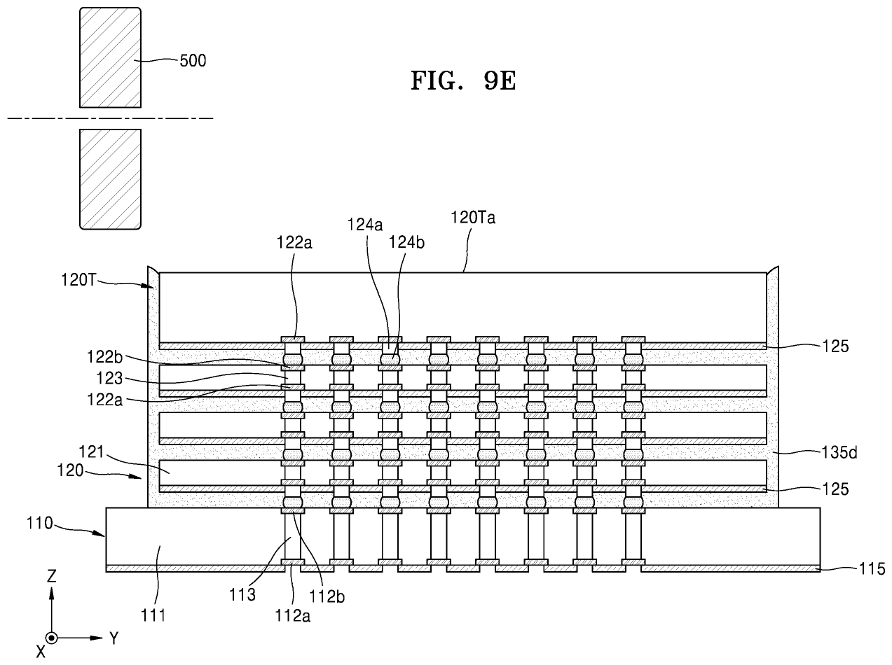

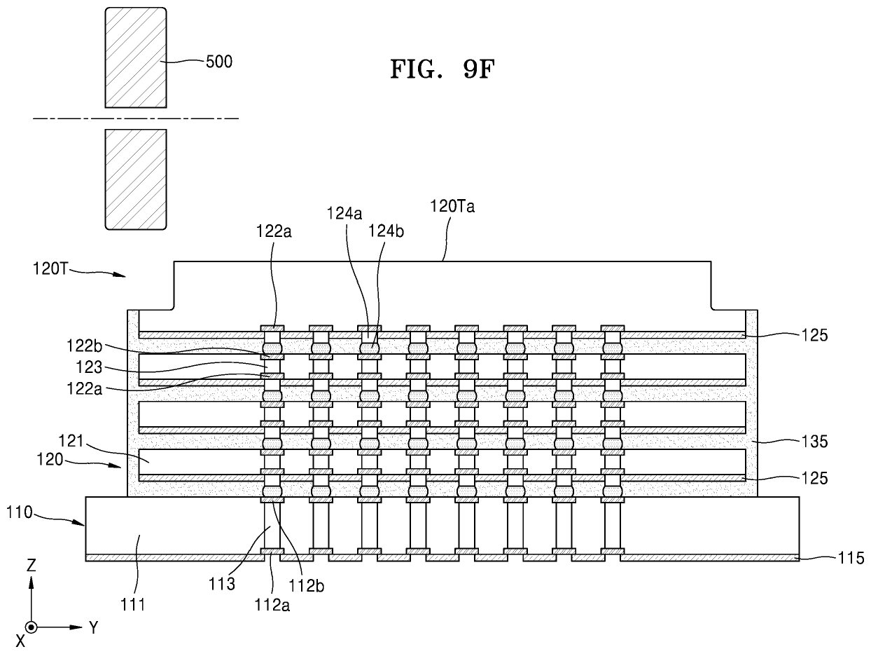

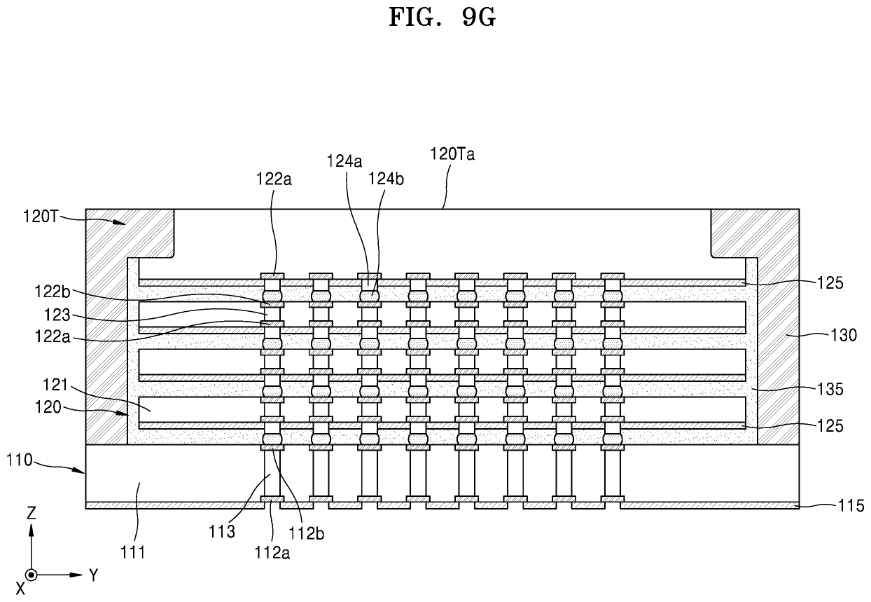

FIG. 8 is a flowchart of a method of manufacturing a semiconductor package, according to an example embodiment. FIGS. 9A through 9G are side views illustrating a method of manufacturing a semiconductor package, according to embodiments.

Referring to FIGS. 8 and 9A, the second semiconductor chip 120 may be attached to the first semiconductor chip 110 which functions as a substrate (S110). In FIG. 9A, the first semiconductor chip 110 is illustrated as in a cut state, but in some embodiments, the first semiconductor chip 110 may include a portion of a semiconductor wafer which is not singulated into separate chips yet.

The second semiconductor chip 120 may include a non-conductive film (NCF) 135f on the second protective insulating layer 125. The NCF 135f may have a thickness h1 that is sufficient enough to bury the inner conductive pillar 124a and the inner conductive cap 124b.

In some embodiments, the NCF 135f may further include one or more types of inorganic particles selected from silica, alumina, zirconia, titania, ceria, magnesia, silicon carbide, and aluminum nitride.

Referring to FIGS. 8 and 9B, after the second semiconductor chip 120 is attached to the first semiconductor chip 110 which is a substrate, the NCF 135f may obtain liquidity (i.e., may be flowable) by applying heat and pressure (S120). When the pressure is applied, due to the liquidity, the non-conductive film 135f may form an under-fill protrusion 135b, which protrudes outwardly from the side surface of the second semiconductor chip 120. For example, the heated and pressurized NCF 135f may protrude outwardly from the side surface of the second semiconductor chip 120 to form the under-fill protrusion 135b, which may be referred to as a preliminary under-fill fillet.

When the inner conductive cap 124b of the second semiconductor chip 120 contacts the first lower surface connection pad 112b of the first semiconductor chip 110 and reflows due to heat, the first semiconductor chip 110 may be adhered to the second semiconductor chip 120. After the first semiconductor chip 110 is adhered to the second semiconductor chip 120, a distance h2 therebetween may be less than the thickness h1 of the NCF 135f before adhesion. Thus, a significant portion of a volume of the NCF 135f may outwardly protrude to form the under-fill protrusion 135b.

In some embodiments, an upper end of the under-fill protrusion 135b may move higher than a surface of the second semiconductor chip 120.

Referring to FIGS. 8 and 9C, another additional second semiconductor chip 120 may be further stacked on the second semiconductor chip 120. Thereafter, after heat and pressure is applied, the inner conductive cap 124b of the second semiconductor chip 120 contacts the inner lower surface connection pad 122b, and reflows due to heat, two second semiconductor chips 120 may be adhered to each other. As described with reference to FIG. 9B, a significant portion of the volume of the NCF 135f may protrude to form an under-fill protrusion 135b.

After repeating the above-described processes, as illustrated in FIG. 9D, the plurality of second semiconductor chips 120 may be stacked on the first semiconductor chip 110, and the stacked structure of the plurality of second semiconductor chips 120 may be provided with a preliminary under-fill fillet 135c that protrudes in a side direction. For example, the preliminary under-fill fillet 135c may extend vertically (e.g., in a Z direction) along side surfaces of the plurality of second semiconductor chip 120. Although four second semiconductor chips 120 are illustrated in FIG. 9D, eight, sixteen, or more second semiconductor chips 120 may be stacked on each other as necessary. The under-fill protrusions 135b in FIGS. 9B and 9C may be connected to each other to form a preliminary under-fill fillet 135c.

The preliminary under-fill fillet 135c may completely surround side surfaces of the second semiconductor chips 120. In some embodiments, the preliminary under-fill fillet 135c may surround side surfaces of at least one of the plurality of second semiconductor chips 120. In some embodiments, an upper end of the preliminary under-fill fillet 135c may protrude higher than the first upper surface 120Ta in a Z direction.

When the upper end of the preliminary under-fill fillet 135c is higher than the first upper surface 120Ta, and the molding resin is formed so that the upper surface of the top semiconductor chip 120T is exposed for smooth heat dissipation, the upper end of the preliminary under-fill fillet 135c may be exposed to the outside of the molding resin. This issue may cause an exterior defect and product reliability deterioration.

Referring to FIGS. 8 and 9E, a side surface portion of the preliminary under-fill fillet 135c may be partially removed by using a removal device 500 (S130).

The partial removal of the preliminary under-fill fillet 135c may be performed by using various methods. For example, the side surface portion of the preliminary under-fill fillet 135c may be partially and mechanically removed by using a grinding blade. The grinding blade may be an example device of the removal device 500. A location of the removal device 500 may be determined, by considering a horizontal width to be obtained by the under-fill fillet 135d.

In some embodiments, the removal device 500 may be oriented to be vertical to the first upper surface 120Ta for obtaining a cut surface vertical to the first upper surface 120Ta.

The present invention is not limited thereto. In some embodiments, partial removal of the preliminary under-fill fillet 135c may be performed by various methods using a laser or the like, other than the grinding blade as an example of the removal device 500.

In some embodiments, an operation of partially removing the side surface portion of the preliminary under-fill fillet 135c may be omitted.

Referring to FIGS. 8 and 9F, an upper end of an under-fill fillet 135d arranged in a side direction of the top semiconductor chip 120T may be partially removed by using the removal device 500 (S140). In some embodiments, the under-fill fillet 135d may extend vertically (e.g., in a Z direction) along side surfaces of the plurality of second semiconductor chips 120. In some embodiments, the under-fill fillet 135d may contact the side surfaces of the plurality of second semiconductor chips 120 and the under-fill layer 135uf. For convenience of description, the under-fill fillet 135d with the upper end partially removed may be referred to as an under-fill fillet 135.

The removal device 500 may be arranged to penetrate a vertical interface between the top semiconductor chip 120T and the under-fill fillet 135d. Thereafter, the periphery 120p of the top semiconductor chip 120T and the upper end of the under-fill fillet 135d may be simultaneously removed to a certain depth by using the removal device 500. The removal may, as described above with reference to FIG. 3, be performed on the periphery 120p of the top semiconductor chip 120 to a certain depth of the top semiconductor chip 120T. In this manner, an upper surface of the periphery 120p of the top semiconductor chip 120T may form the same flat surface as a planar surface of an upper end of the under-fill fillet 135.

In some embodiments, as described above with reference to FIG. 3, the certain depth may be about 40% to about 80% of the total thickness of the top semiconductor chip 120T.

By using the removal, an L-shaped recess may be formed at the side surface of the top semiconductor chip 120T. On the other hand, when the removal device 500 forms the L-shaped recess at the side surface of the third upper surface 120Td, a curved surface of a certain curvature may be formed between the side surface 120Tb and the second upper surface 120Tc (refer to FIG. 3) due to a shape of the grinding blade of the removal device 500 or the laser cutting characteristics.

Referring to FIGS. 8 and 9G, the molding resin 130 may be formed to surround the side surface of the top semiconductor chip 120T, and upper surfaces and the side surfaces of the under-fill fillet 135 (S150).

An upper surface of the top semiconductor chip 120T (that is, the first upper surface 120Ta) may be exposed from the molding resin 130. The molding resin 130 may cover the entire upper surface and the entire side surface of the under-fill fillet 135. Accordingly, the under-fill fillet 135 may not be exposed to the outside of the molding resin 130.

As described above, the first semiconductor chip 110 may include a portion of a semiconductor wafer, which is not singulated yet. In this case, after the molding resin 130 is formed, the first semiconductor chip 110 may be separated to form individual semiconductor packages by a dicing process.

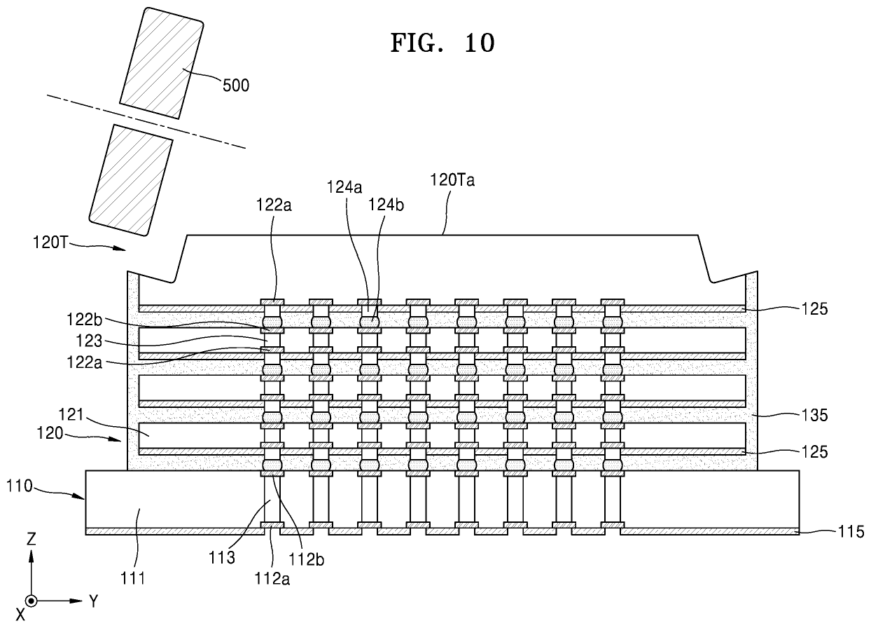

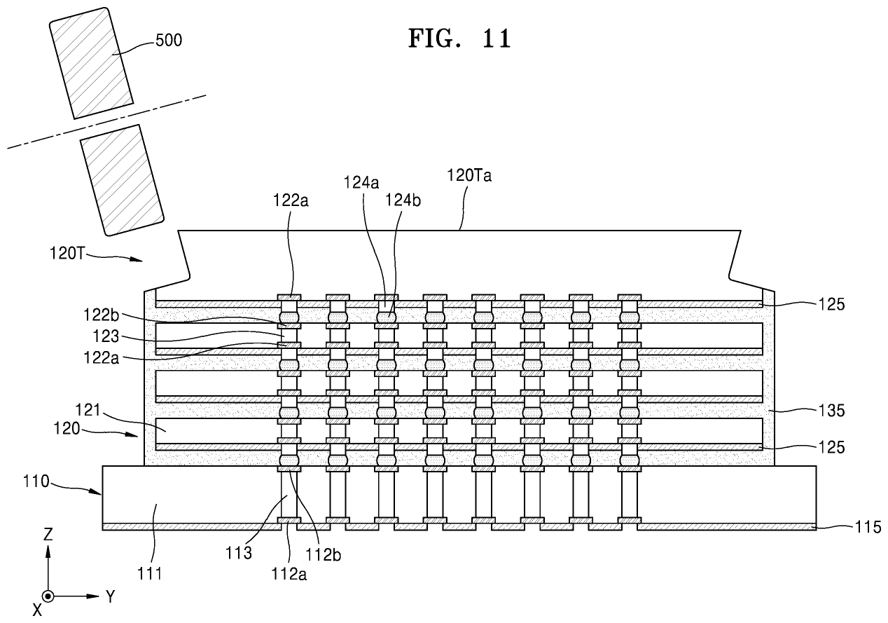

FIGS. 10 and 11 are schematic diagrams illustrating a method of forming the L-shaped recess as illustrated in FIGS. 4 and 5, respectively.

Referring to FIGS. 10 and 11, by adjusting a posture of the removal device 500 so that the removal device 500 forms an acute angle or an obtuse angle with respect to the first upper surface 120Ta, an angle formed between the side surface of the removal device 500 and the first upper surface 120Ta may be adjusted. Due to a shape of the removal device 500, the side surface thereof and the second upper surface 120Tc (refer to FIGS. 4 and 5) may substantially form about 90 degrees.

Depending on cases, it may be difficult to maintain the removal device 500 to be precisely vertical with respect to the first upper surface 120Ta, and thus, by maintaining the removal device 500 to be slanted at an angle with respect to the first upper surface 120Ta as illustrated in FIGS. 10 and 11, a purpose of a partial removing of the upper end of the under-fill fillet 135d may be easily achieved.

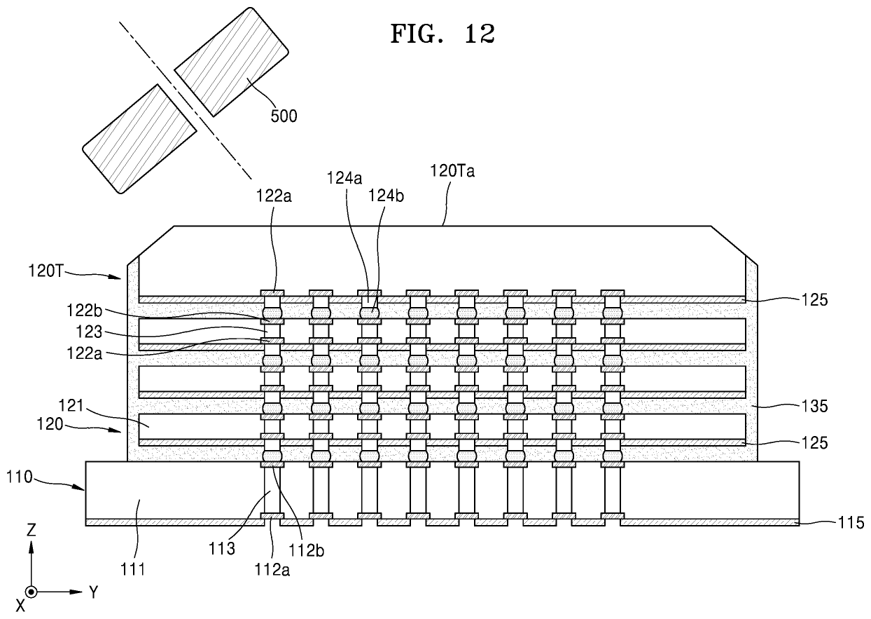

FIG. 12 is a schematic diagram for describing a method of forming the third upper surface 120Td slanted at an angle with respect to the first upper surface 120Ta in FIGS. 6 and 7.

Referring to FIG. 12, an upper corner of the top semiconductor chip 120T may be chamfered by using the removal device 500. In this case, the upper end of the under-fill fillet 135d may be removed together while the upper corner of the top semiconductor chip 120T is chamfered.

Depending on a slanted angle of the removal device 500 with respect to the first upper surface 120Ta for chamfering, an angle formed by the first upper surface 120Ta and the third upper surface 120Td (refer to FIG. 7) may be determined. Because the chamfering and the partial removal of the upper end of the under-fill fillet 135d are simultaneously performed, the third upper surface 120Td (refer to FIG. 7) may be coplanar with the planar surface 135T at the uppermost end of the under-fill fillet 135.

While the inventive concept has been particularly shown and described with reference to embodiments thereof, it will be understood that various changes in form and details may be made therein without departing from the spirit and scope of the following claims.

1. A semiconductor package comprising:
a substrate;
a plurality of semiconductor devices stacked on the substrate;
an under-fill fillet on side surfaces of the plurality of semiconductor devices; and
a molding resin surrounding the plurality of semiconductor devices,
wherein an uppermost end of the under-fill fillet comprises a planar surface coplanar with an upper surface of a periphery of an uppermost semiconductor device among the plurality of semiconductor devices, and
wherein the molding resin completely covers the planar surface.

2. The semiconductor package of claim 1,
wherein the uppermost semiconductor device comprises:
a first upper surface;
a side surface connected to the first upper surface; and
a second upper surface connected to the side surface and located below the first upper surface, and
wherein the second upper surface comprises the upper surface of the periphery.

3. The semiconductor package of claim 2,
wherein the first upper surface and the second upper surface form an angle difference equal to or less than about 10 degrees (°).

4. The semiconductor package of claim 2,
wherein the first upper surface is substantially parallel with the second upper surface.

5. The semiconductor package of claim 2,
wherein the first upper surface and the side surface form an angle between about 60 degrees and about 150 degrees.

6. The semiconductor package of claim 5,
wherein the second upper surface and the side surface form an angle of about 90 degrees.

7. The semiconductor package of claim 2,
wherein the uppermost semiconductor device further comprises:
a curved surface between the side surface and the second upper surface, and
wherein the curved surface has a curvature radius between about 1 μm and about 20 μm.

8. The semiconductor package of claim 1,
wherein the uppermost semiconductor device comprises:
a first upper surface that is uppermost;
a third upper surface connected to the first upper surface and slanted at an angle with respect to the first upper surface; and
a side surface connected to the third upper surface and having an angle of about 90 degrees with respect to the first upper surface, and
wherein the third upper surface comprises an upper surface of the periphery.

9. The semiconductor package of claim 8,
wherein the third upper surface forms an angle between about 5 degrees and about 80 degrees with respect to the first upper surface.

10. The semiconductor package of claim 8,
wherein the third upper surface contacts only the molding resin.

11. The semiconductor package of claim 1,
wherein the under-fill fillet completely surrounds side surfaces of at least one of the plurality of semiconductor devices.

12. A semiconductor package comprising:
a package substrate;
an interposer substrate on the package substrate;
a first semiconductor device and a second semiconductor device arranged side by side on the interposer substrate; and
a molding resin surrounding side surfaces of each of the first semiconductor device and the second semiconductor device,
wherein the first semiconductor device comprises:
a buffer chip;
a plurality of memory devices stacked on the buffer chip and connected with each other via through-silicon vias (TSVs); and
an under-fill fillet on side surfaces of the plurality of memory devices,
wherein an uppermost end of the under-fill fillet comprises a planar surface coplanar with an upper surface of a periphery of an uppermost memory device among the plurality of memory devices, and
wherein the molding resin completely covers the planar surface.

13. The semiconductor package of claim 12,
wherein the uppermost memory device comprises:
a first upper surface;
a side surface connected to the first upper surface; and
a second upper surface connected to the side surface and located below the first upper surface, and
wherein a level difference between the first upper surface and the second upper surface has a value between about 80 μm and about 200 μm.

14. The semiconductor package of claim 13,
wherein the planar surface of the uppermost end of the under-fill fillet is coplanar with the second upper surface of the uppermost memory device, and
wherein a width of the planar surface of the uppermost end of the under-fill fillet has a value between about 20 μm and about 80 μm.

15. The semiconductor package of claim 13,
wherein a width of the second upper surface has a value between about 40 μm and about 100 μm.

16. The semiconductor package of claim 12,
wherein the under-fill fillet comprises one or more types of inorganic particles selected from the group consisting of silica, alumina, zirconia, titania, ceria, magnesia, silicon carbide, and aluminum nitride.

17. The semiconductor package of claim 12,
wherein the uppermost memory device comprises:
a first upper surface;
a third upper surface connected to the first upper surface and slanted at an angle with respect to the first upper surface; and
a side surface connected to the third upper surface and forming an angle of about 90 degrees with respect to the first upper surface, and
wherein the uppermost end of the under-fill fillet comprises a planar surface coplanar with the third upper surface.

18. The semiconductor package of claim 12, further comprising:
a heat dissipating member covering upper surfaces of the first semiconductor device and the second semiconductor device.

19. The semiconductor package of claim 12,
wherein the interposer substrate comprises a semiconductor substrate comprising a redistribution structure, and
wherein the package substrate comprises a printed circuit board (PCB).

20. A semiconductor package comprising:
a substrate;
a plurality of semiconductor devices stacked on the substrate;
an under-fill fillet on side surfaces of the plurality of semiconductor devices; and
a molding resin surrounding the plurality of semiconductor devices,
wherein a side surface of an uppermost semiconductor device among the plurality of semiconductor devices has an L-shaped recess, and
wherein an uppermost end of the under-fill fillet is coplanar with a horizontal surface of the L-shaped recess.

21-27. (canceled)
